(19) United States
(12) Patent Application Publication
(10) Pub. No.: US 2026/0266896 A1
(43) Pub. Date: Sep. 10, 2026

(54) TEST STRUCTURE AND TEST METHOD FOR SEMICONDUCTOR DEVICE

(71) Applicant: Winbond Electronics Corp., Taichung City (TW)

(72) Inventors: Tai-An Hou, Kaohsiung (TW); Pei-Hsiu Peng, Kaohsiung (TW)

(73) Assignee: Winbond Electronics Corp., Taichung City (TW)

(21) Appl. No.: 19/531,692

(22) Filed: Feb. 6, 2026

(30) Foreign Application Priority Data
Mar. 7, 2025 (TW) 114108599

(51) Int. Cl. G01R 31/28; G11C 29/44; H10P 74/00

(52) U.S. Cl. CPC G01R 31/2884; G11C 29/44; H10P 74/277

(57) ABSTRACT

A test method of a semiconductor device includes the following. Multiple test elements of a test structure are selected, and multiple first electrical parameters of the test elements are obtained by a row decoder and a column decoder of the test structure. Acceding to the first electrical parameters, it is determined whether each of the test elements is a weak element. The weak element is selected by the row decoder and the column decoder, and an abnormal-cause analysis is performed on the weak element. A test structure of the semiconductor device is also provided.

### CROSS-REFERENCE TO RELATED APPLICATION

This application claims the priority benefit of Taiwan application serial no. 114108599, filed on Mar. 7, 2025. The entirety of the above-mentioned patent application is hereby incorporated by reference herein and made a part of this specification.

### BACKGROUND

### Technical Field

The disclosure relates to a test structure and a test method, and more particularly, to a test structure and a test method for a semiconductor device that may reduce test costs.

### Description of Related Art

In order to perform various tests and verifications during a semiconductor manufacturing process to ensure quality and performance of the manufacturing process, a test structure, such as a test key or a test element group (TEG), is usually disposed on a scribe line of a wafer. Specifically, as each of steps of the manufacturing process is carried out to manufacture elements within the chip area, the test structure is simultaneously manufactured in the wafer's scribe line. Subsequently, various parameters of the test structure are measured during a wafer acceptance test, serving as indicators to verify the normality of both the manufacturing process and the elements. This approach enables effective quality control of the product.

In general, the test structure may include multiple test elements, such as transistors. However, during the wafer acceptance test, only a portion of the test elements can be measured due to limitations in the number of test pads (or probes) and layout considerations of associated measurement metal lines. As a result, only a coarse localization of abnormal areas can be achieved. With continued process scaling and increased device density, test results tend to become less accurate, thereby creating a bottleneck for yield improvement. Enhancing test accuracy would require the inclusion of additional test structures, which in turn increases test costs. Therefore, the test efficiency of the existing test structures and their corresponding test methods remains inadequate to meet cost-reduction demands.

### SUMMARY

The disclosure provides a test structure and a test method for a semiconductor device, which overcome the shortcomings of the prior art, including low accuracy in locating abnormal areas, insufficient measurement precision, and low test efficiency.

A test method of a semiconductor device in the disclosure includes the following. A test structure is provided. The test structure includes a first portion. The first portion includes a first test element group, a first pad set, a row decoder, and a column decoder. The first test element group includes multiple first test elements. The first pad set includes multiple first pads. The row decoder and the column decoder are coupled between the first test element group and the first pad set. The first test elements are selected, and multiple first electrical parameters of the first test elements are obtained by the row decoder and the column decoder of the test structure. A number of the first pads is less than a number of the obtained first electrical parameters. It is determined whether each of the first test elements is a weak element according to the first electrical parameters. The weak element is selected by the row decoder and the column decoder, and an abnormal-cause analysis is performed on the weak element.

A test structure of a semiconductor device in the disclosure includes a first portion. The first portion includes a first test element group, a first pad set, a row decoder, and a column decoder. The first test element group includes multiple first test elements. The first pad set includes multiple first pads. The row decoder and the column decoder are coupled between the first test element group and the first pad set, configured to select the first test elements, and obtain multiple first electrical parameters of the first test elements. A number of the first pads is less than a number of the obtained first electrical parameters. It is determined whether each of the first test elements is a weak element according to the first electrical parameters. The weak element is selected by the row decoder and the column decoder, and an abnormal-cause analysis is performed on the weak element.

Based on the above, the test structure and the test method for the semiconductor device in the disclosure may improve the accuracy in locating abnormal areas, the precision of the test results, and the test efficiency, thereby improving yields and reducing test costs.

### BRIEF DESCRIPTION OF THE DRAWINGS

FIG. 1 is a schematic diagram of a test structure according to an embodiment of the disclosure.

FIG. 2 is a schematic circuit diagram of a test structure according to an embodiment of the disclosure.

FIG. 3 is a schematic diagram of a configuration table of a pad set according to an embodiment of the disclosure.

FIG. 4 is a flow chart of a test method according to an embodiment of the disclosure.

FIG. 5A is a schematic diagram of a first electrical parameter table according to an embodiment of the disclosure.

FIG. 5B is a schematic diagram of measurement of multiple second electrical parameters according to an embodiment of the disclosure.

FIG. 6 is a schematic diagram of a test structure according to another embodiment of the disclosure.

FIG. 7 is a schematic diagram of a second portion of a test structure according to another embodiment of the disclosure.

FIG. 8 is a schematic diagram of a configuration table of a pad set according to another embodiment of the disclosure.

FIG. 9 is a flow chart of a test method according to another embodiment of the disclosure.

FIG. 10 is a schematic diagram of a coarse test electrical parameter table according to another embodiment of the disclosure.

### DETAILED DESCRIPTION OF DISCLOSED EMBODIMENTS

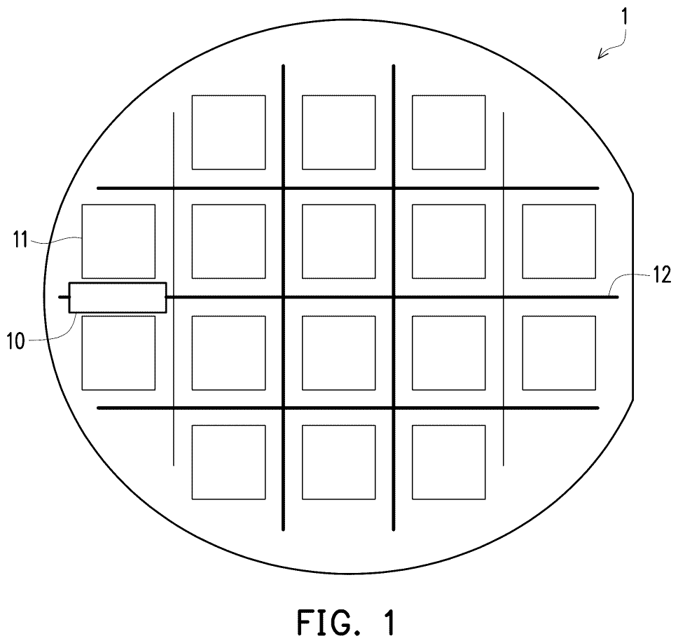

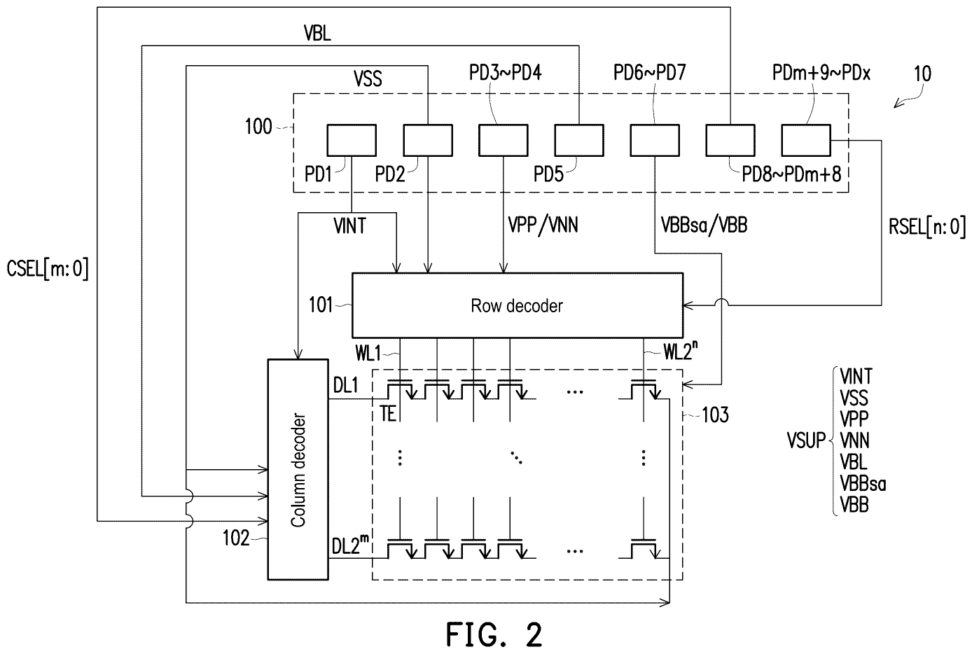

As shown in FIG. 1, a test structure 10 according to an embodiment of the disclosure may be disposed on a scribe line 12 of a wafer 1 and located between multiple dies 11. The test structure 10 is configured to perform an electrical or functional test, such as a wafer acceptance test (WAT), to determine whether quality and reliability of the wafer 1 meet requirements. In detail, as shown in FIG. 2, the test structure 10 according to an embodiment of the disclosure includes a pad set 100, a row decoder 101, a column decoder 102, and a test element group (TEG) 103. Through this arrangement, the test performed on the test structure 10 will not be limited by the number of pads and a layout constraints of associated measurement metal lines, thereby allowing testing of a number of test elements greater than the number of pads. This improves the accuracy of locating abnormal areas, the precision of test results and test efficiency, thereby improving yields and reducing test costs.

The pad set 100 includes x pads PD1 to PDx, which are coupled to the row decoder 101, the column decoder 102, and the TEG 103, and are configured to receive a driving signal VSUP, a row select signal RSEL[n:0], and a column select signal CSEL[m:0]. The TEG 103 includes multiple test elements TE. The test elements TE may be arranged in an array. First terminals (e.g., gates) of the test elements TE are connected to the row decoder 101 through word lines WL1 to WL2ⁿ. Second terminals (e.g., drains) are connected to the column decoder 102 through data lines DL1 to DL2^{m}. Third terminals (e.g., sources) are commonly connected to the pad PD2. The driving signal VSUP may be provided to the test element TE in the TEG 103 to provide an operating voltage or other electrical signals required for operation of the test element TE. The row select signal RSEL[n:0] and the column select signal CSEL[m:0] may be respectively provided to the row decoder 101 and the column decoder 102 so as to select one of the test elements TE for testing. In this way, by changing the row select signal RSEL[n:0] and the column select signal CSEL[m:0], the selected test element TE in the TEG 103 may be tested, and electrical parameters of the selected test element TE may be obtained through the column decoder 102 or the pad PD2. Thus, the test structure 10 in this embodiment may obtain test results of a greater number of the test elements TE through a smaller number of the pads, such that the test is not limited by the number of pads or by the layout constraints of associated measurement metal lines. In a preferred embodiment, the test structure 10 may obtain the test results of all the test elements TE in the TEG 103, thereby improving the accuracy of the test results.

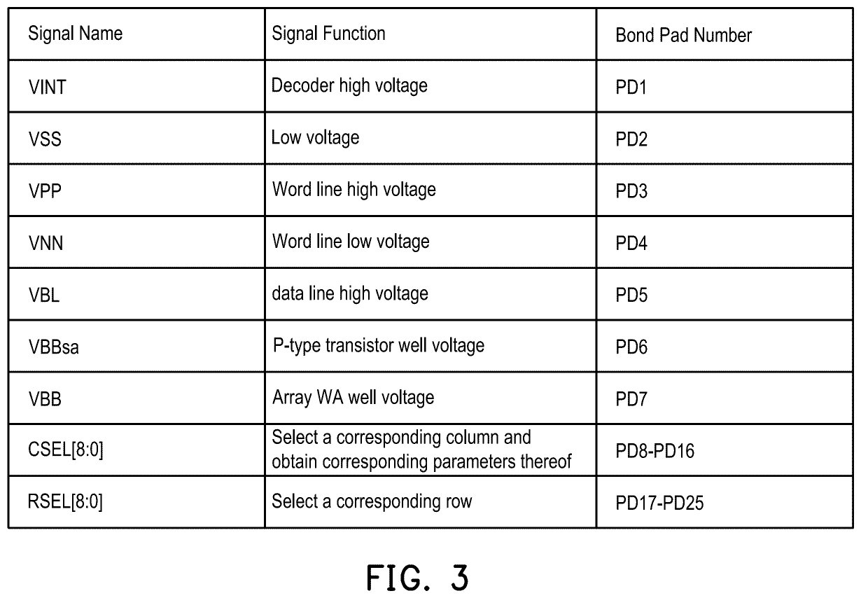

Referring to both FIGS. 2 and 3, the aforementioned x may be, for example, 25, m may be, for example, 8, and n may be, for example, 8. Specifically, the pads PD1 and PD3 to PD7 may be used to provide the driving signal VSUP. The pads PD8 to16 may be used to provide the column select signal CSEL[8:0] to select a corresponding column. The pads PD17 to 25 may be used to provide the row select signal RSEL[8:0] to select a corresponding row. The driving signal VSUP may include a decoder high voltage VINT, a low voltage VSS, a word-line high voltage VPP, a word-line low voltage VNN, a bit-line high voltage VBL, a P-type transistor well voltage VBBsa, and an array WA well voltage VBB. In this embodiment, the pad PD1 is configured to provide the decoder high voltage VINT to the row decoder 101 and the column decoder 102. The pad PD2 is configured to provide the low voltage VSS to the row decoder 101, the column decoder 102, and the source terminal of the test element TE. The pad PD3 is configured to provide the word-line high voltage VPP to the row decoder 101, and the pad PD4 is configured to provide the word-line low voltage VNN to the row decoder 101. The pad PD5 is configured to provide the bit-line high voltage VBL to the column decoder 102. The pads PD6 and PD7 are configured to respectively provide the P-type transistor well voltage VBBsa and the array WA well voltage VBB to a well area of the TEG 103. According to the column select signal CSEL[8:0] and the row select signal RSEL[8:0], the electrical parameters of the selected test element TE may be obtained from the pads PD8 to 16 or the pad PD2.

In this example, the column decoder 102 may select one column of the TEG 103 by decoding the binary column select signal CSEL[8:0] into a one-hot signal. Similarly, the row decoder 101 may also select one row of the TEG 103 by decoding the binary row select signal RSEL[8:0] into a one-hot signal. In this way, according to the disclosure, only 25 pads required to be disposed to select multiple test elements TE from 262144 test elements TE to for testing, so as to obtain the corresponding electrical parameters.

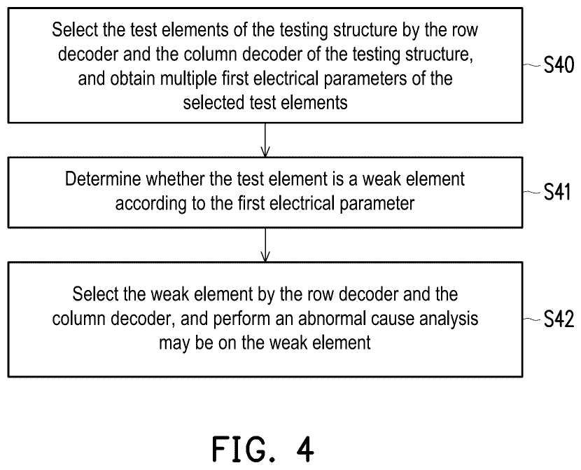

A test method according to an embodiment of the disclosure shown in FIG. 4 may be applied to the test structure 10 shown in FIGS. 1 and 2. The test method in FIG. 4 includes steps S40 to S42.

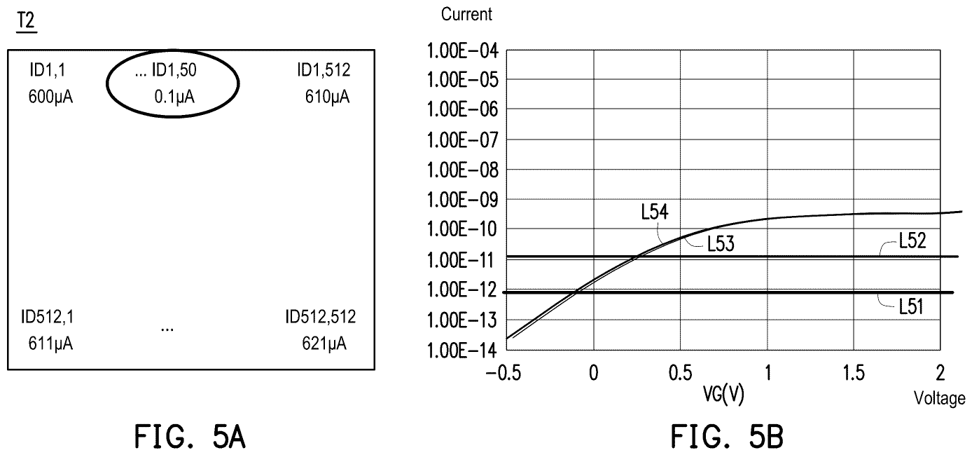

In step S40, the test elements of the TEG of the test structure are selected by the row decoder and the column decoder of the test structure, and multiple first electrical parameters of the selected test elements are obtained. For example, referring to FIG. 5A, the test structure 10 may select one of the test elements TE as the selected test element through a row select signal RSEL and a column select signal CSEL in step S40, and obtain the corresponding first electrical parameters thereof. Furthermore, by changing the row select signal RSEL and the column select signal CSEL input to the test structure 10, the selected test elements TE may be sequentially switched in a predetermined range, and the first electrical parameter of each of the test elements TE in the predetermined range may be obtained. In this example, the test element TE may be, for example, a metal oxide semiconductor field effect transistor (MOSFET), and the first electrical parameter obtained by the test structure 10 may be, for example, a drain current ID of each of transistors. In an embodiment, all the test elements TE are selected for testing by the row decoder 101 and the column decoder 102, and a first electrical parameter table T2 as shown in FIG. 5A is generated, which records the first electrical parameter of each of the transistors tested, such as drain currents ID1,1 to ID512,512.

In step S41, it may be determined whether the test element TE is a weak element according to the first electrical parameter. Specifically, after the first electrical parameter of the selected test element TE is obtained, by comparing the first electrical parameter of each of the selected test elements TE with a preset condition, the selected test element TE having the first electrical parameter not meeting the preset condition may be determined to be the weak element. In some embodiments, the preset condition represents a normal or acceptable electrical parameter range of the test elements, which may be determined based on measured electrical parameter characteristics or element characteristics. The preset condition may be dynamic or static. For example, the static preset condition may have a preset boundary value. A boundary value of the dynamic preset condition may be related to a statistical value of the first electrical parameters (e.g., a group statistical range generated by calculating a mean value and a standard deviation), and the first electrical parameter that is an outlier relatively may be selected through the dynamic preset condition. In addition, if all the first electrical parameters meet the preset condition, it is determined to be passed, and the test is terminated.

In step S42, the weak element may be selected by the row decoder 101 and the column decoder 102, and an abnormal-cause analysis may be performed on the weak element. Specifically, after an address of the weak element is determined in step S41, the weak element may be selected by controlling the row decoder 101 and the column decoder 102, and a second electrical parameter of the weak element may be obtained. For example, when the test element TE is the MOSFET, and the first electrical parameter is the drain current, the second electrical parameter obtained in step S42 may include four-terminal current parameters of the weak element. For example, by the row decoder 101 and the column decoder 102, a gate current of the weak element may be obtained from the pads PD17 to 25, a source current of the weak element may be obtained from the pad PD2, a well current of the weak element may be obtained from the pad PD7, and a drain current of the weak element may be obtained from the pads PD8 to 16.

Referring to FIG. 5B, a direct-current (DC) sweep diagram illustrating the relationship between the four-terminal currents of the weak element and the gate voltage of the weak element is shown. In detail, the four-terminal current parameter curves L51-L54 measured from the weak element respectively may correspond to the well current, the gate current, the source current, and the drain current of the weak element. As shown in FIG. 5B, as a gate voltage VG on a horizontal axis changes, the curves L51 and L52 corresponding to the well current and the gate current of the weak element remain substantially equal. On the other hand, the curves L53 and L54 corresponding to the drain current and the source current of the weak element increase with the gate voltage and saturate at a value slightly higher than the gate current, thus indicating that the weak element may be the source of the abnormal behavior. Accordingly, based on the second electrical parameters measured in step S42, the type of abnormality associated with the weak element can be further determined. In this example, the abnormality of the weak element may be attributable to a short circuit between the drain and the source of the weak element. In some embodiments, the second electrical parameter may also be obtained directly from measurements of the weak element or may be derived from other electrical characteristics. For example, the second electrical parameter may be a threshold voltage (Vth), an on-current (Ion), and/or an off-current (Ioff) of the transistor, or other suitable electrical parameters.

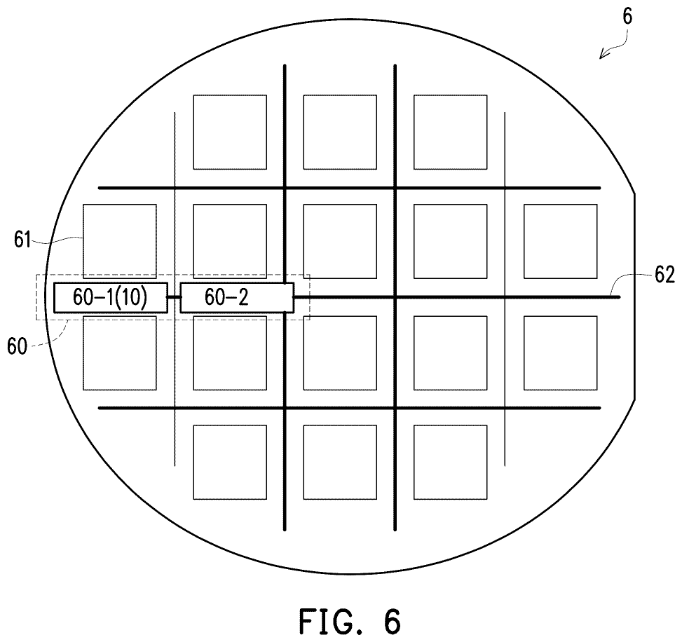

FIG. 6 is a schematic diagram of a test structure 60 according to another embodiment of the disclosure. The test structure 60 may be disposed on a scribe line 62 and between multiple dies 61. In detail, the test structure 60 may include a first portion 60-1 and a second portion 60-2. Regarding a structure and an operating method of the first portion 60-1, reference may be made to previous descriptions of the test structure 10. Therefore, the same details will not be repeated in the following. In other words, the first portion 60-1 of the test structure 60 includes the pad set 100, the row decoder 101, the column decoder 102, and the TEG 103.

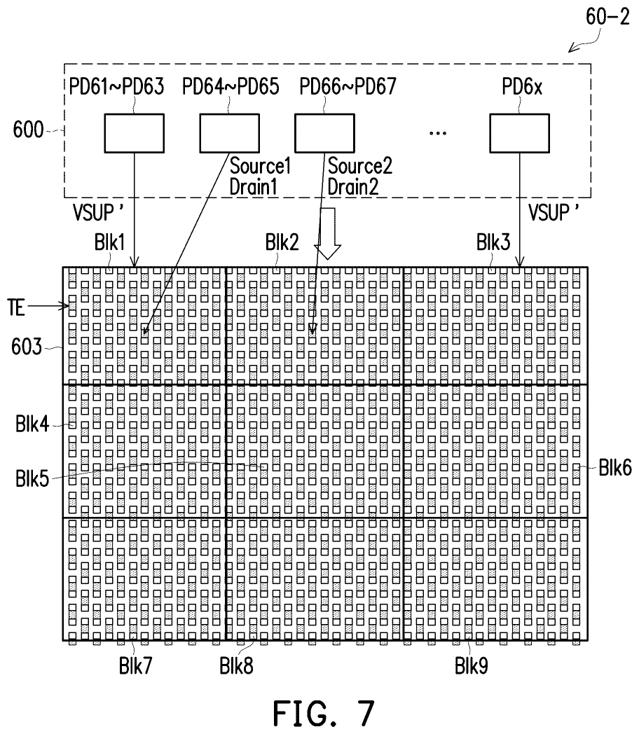

As shown in FIG. 7, the second portion 60-2 of the test structure 60 includes a pad set 600 and a TEG 603. The pad set 600 includes pads PD61 to PD6x. It should be noted that the second portion 60-2 of the test structure 60 does not have the row decoder 101 and the column decoder 102.

In an embodiment, the TEG 603 of the second portion 60-2 of the test structure 60 may be configured the same as the TEG 103, and the TEG 603 and the TEG 103 may each be divided into 9 test partitions Blk1 to Blk 9. Each of the test partitions Blk1 to Blk 9 includes the test elements TE. Each terminal of one test element TE in each of the test partitions Blk1 to Blk9 is directly coupled to one of the pads PD61 to PD6x. According to the test method in this embodiment, a coarse test may be performed on the test elements TE among the test partitions Blk1 to Blk9 of the TEG 603 directly coupled to the pad set 600 by the test structure 60. Since the TEG 603 and the TEG 103 have the same test elements TE and partitions, the abnormal test partitions determined according to a coarse test result of the TEG 603 may be used to select the corresponding test partitions of the first portion 60-1 for fine testing (i.e., steps S40 to S42 mentioned above). In this way, the fine test may be performed only on the abnormal test partitions of the TEG 103, which may reduce the overall test time and saving the test costs.

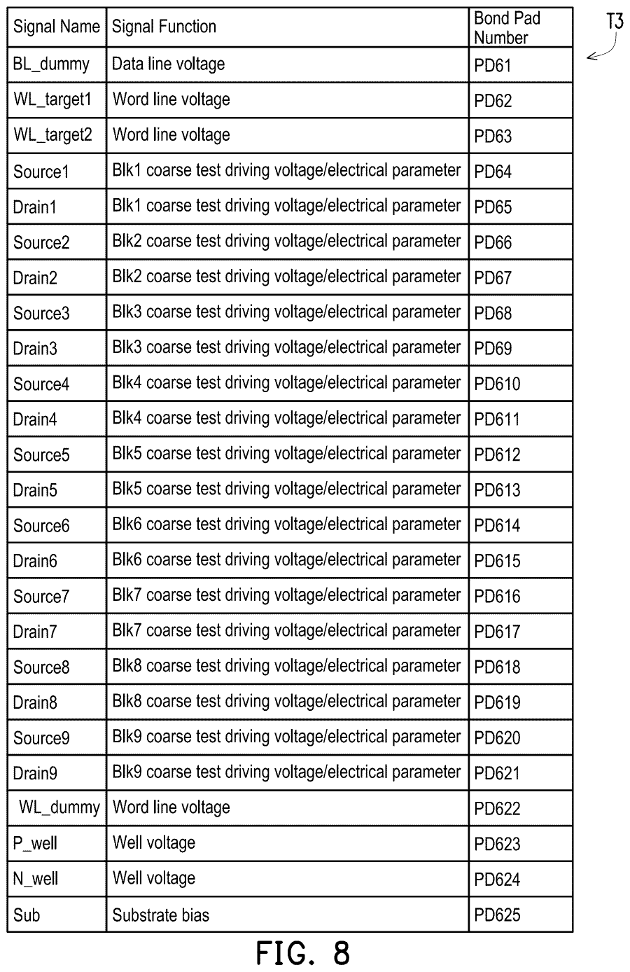

FIG. 8 is an example of a configuration table T3 of the pad set 600. Referring to both FIGS. 7 and 8, the aforementioned x is, for example, 25. That is, the pad set 600 may include 25 pads PD61 to PD625. Specifically, the pads PD61 to PD63 and PD622 to PD625 may be used to transmit a coarse test driving signal VSUP′, and the pads PD64 to PD621 may be used to transmit coarse test electrical parameters or coarse test driving voltages Source1 to Source9 and Drain1 to Drain9 of the source or the drain of the test element TE directly coupled to the pad set 600. The coarse test driving signal VSUP′ may include coarse test driving voltages (e.g., a bit line voltage BL_dummy, word line voltages WL_target1, WL_target2, and WL_dummy, well voltages P_well and N_well, and a substrate bias Sub) used to provide an appropriate bias to data lines, word lines, transistor well areas, or substrates. In the example of FIG. 8, each of the test elements TE directly coupled to the pad set 600 is allocated with at least four pads. For example, the source of the test element TE of the test partition Blk1 is configured to be directly coupled to the pad PD64 to receive the coarse test driving voltage, and the drain of the test element TE of the test partition Blk1 is configured to be directly coupled to the pad PD65 to provide the drain current to the pad PD65 as the coarse test electrical parameter. The gate and a base of the test element TE of the test partition Blk1 are respectively configured to be directly coupled to the pads PD62 and PD623 to receive the coarse test driving voltage.

In this embodiment, the number of pads of the pad set 100 of the first portion 60-1 of the test structure 60 is less than the number of obtained first electrical parameters, and the number of pads of the pad set 600 of the second portion 60-2 of the test structure 60 is greater than the number of obtained coarse test electrical parameters. In this way, an area occupied by the test structure 60 may be reduced, the layout of the measurement metal lines may be simplified, and the test efficiency may be improved.

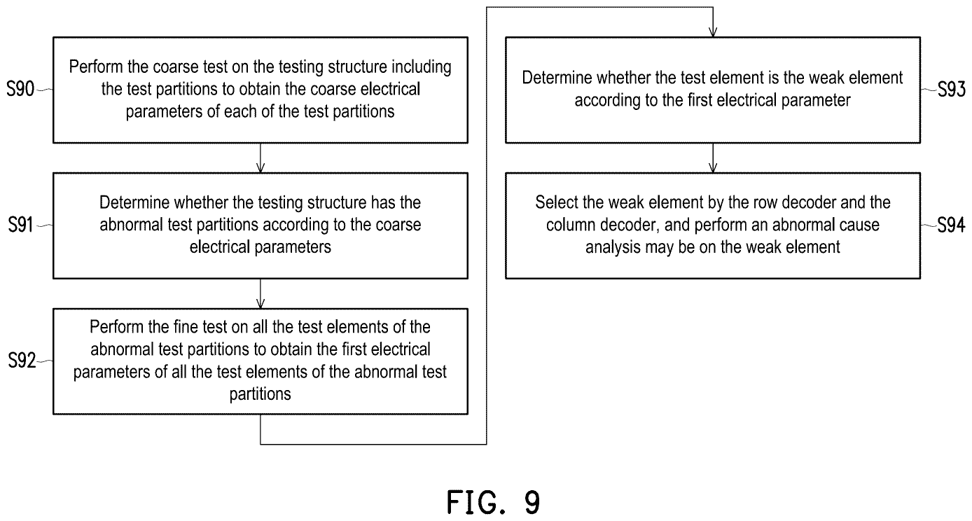

FIG. 9 is a flow chart of a test method according to another embodiment of the disclosure which may be applied to the test structures 10 and 60 shown in FIGS. 1 and 2, 6 and 7, and includes steps S90 to S94.

In detail, in step S90, the coarse test is performed on the test structure including the test partitions to obtain the coarse test electrical parameters of the respective test partitions. Specifically, in an embodiment, the coarse test may be performed on the second portion 60-2 of the test structure 60 including the test partitions Blk1 to Blk9. The coarse test may include applying the coarse test driving signal VSUP′ to the pad set 600, such that the test elements TE whose terminals are directly coupled to the pad set 600 receive the coarse test driving voltage VSUP′, and then the coarse test electrical parameters are obtained from the test elements at the same time through the pads. In another embodiment, the coarse test may be performed on the test structure 10 including the test partitions Blk1 to Blk9. The coarse test may include applying the coarse test driving signal (e.g., VSUP) to the pad set 100, selecting some of the test elements TE from each of the test partitions Blk1 to Blk9 through the row decoder 101 and the column decoder 102, and then obtaining the coarse test electrical parameters from the selected test elements TE through the corresponding pads.

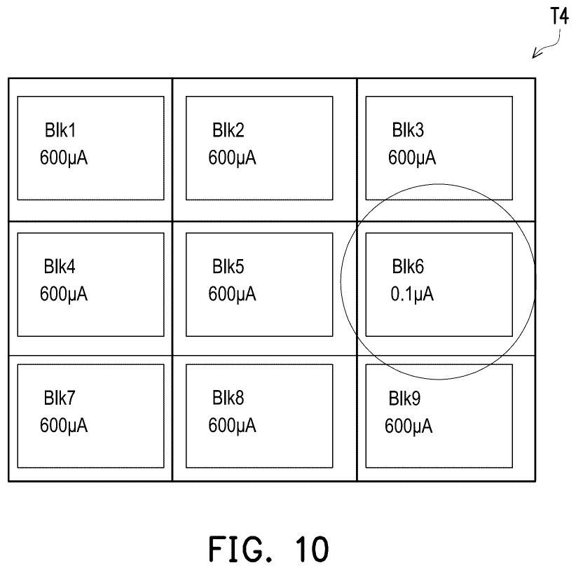

In step S91, it is determined whether the test structure has the abnormal test partitions according to the coarse test electrical parameters. Referring to a coarse test electrical parameter table T4 shown in FIG. 10, which lists the coarse test electrical parameters obtained from the test partitions. Specifically, each coarse test electrical parameter of the test partition is compared with the preset condition. If the coarse test electrical parameter does not meet the preset condition, the corresponding test partition is determined to be the abnormal test partition. In the embodiment shown in FIG. 10, the coarse test electrical parameter of 0.1 μÅ of the test partition Blk6 does not meet the preset condition, and thus the test partition Blk6 is determined to be the abnormal test partition. If all the coarse test electrical parameters of the test partitions meet the preset condition, it is determined to be passed, and the test is terminated.

In step S92, the fine test is performed on all the test elements of the abnormal test partitions to obtain the first electrical parameters of all the test elements of the abnormal test partitions. Specifically, in an embodiment, the test partition Blk6 of the TEG 603 of the second portion 60-2 of the test structure 60 is determined to be the abnormal test partition. Since the TEG603 is configured the same as the TEG103, the test elements TE of the test partition Blk6 of the TEG 103 may be sequentially selected and switched through the row decoder 101 and the column decoder 102 until the fine test is performed on all the test elements TE of the test partition Blk6 to obtain the first electrical parameters of all the test elements TE of the test partition Blk6. In another embodiment, when the test partition Blk6 of the test structure 10 is determined to be the abnormal test partition, the test elements TE of the test partition Blk6 of the TEG 103 may be sequentially selected and switched through the row decoder 101 and the column decoder 102 until the fine test is performed on all the test elements TE of the test partition Blk6 to obtain the first electrical parameters of all the test elements TE of the test partition Blk6. In an embodiment, the first electrical parameters and the coarse test electrical parameters may both be the drain currents.

In step S93, whether the test element TE is the weak element may be determined according to the first electrical parameter. Details of step S93 are the same as those of step S41. Therefore, the same details will not be repeated in the following.

In step S94, the weak element may be selected by the row decoder and the column decoder, and the abnormal-cause analysis may be performed on the weak element. Details of step S94 are the same as those of step S42. Therefore, the same details will not be repeated in the following.

Based on the above, the test structure and the test method of the semiconductor device in the disclosure may improve the positioning accuracy of the abnormal area, the accuracy of the test results, and the test efficiency, thereby improving the yields and reducing the test costs.

The semiconductor device in the disclosure may be any integrated circuit, including but not limited to any integrated circuit including the metal oxide semiconductor field effect transistor, such as a dynamic random-access memory (DRAM), a flash memory, or a resistive random-access memory. In addition, for a three-dimensional stacked integrated circuit, the test structure and the test method in the disclosure may significantly improve the yields and reduce the test costs.

The disclosure is adapted to manufacture a miniaturized semiconductor device to increase the total number of dies on the wafer. In addition, the test structure and the test method of the semiconductor device according to the disclosure are beneficial to reduce the number of test structures or TEGs to be disposed when the manufacturing process is miniaturized, and a capacity and/or a bandwidth are improved, thereby reducing process materials and the test costs. Therefore, the disclosure may reduce manufacturing costs and energy consumption of manufacturing a single IC, and reduce manufacturing energy consumption of subsequent packaging, thereby reducing carbon emissions in a production process of the semiconductor device. In addition, since the yield of the semiconductor device in the disclosure is improved, the present disclosure provides a green semiconductor technology.

What is claimed is:

1. A test method of a semiconductor device, comprising:
providing a test structure comprising:
a first portion, comprising:
a first test element group comprising a plurality of first test elements;
a first pad set comprising a plurality of first pads; and
a row decoder and a column decoder coupled between the first test element group and the first pad set;
selecting the plurality of first test elements, and obtaining a plurality of first electrical parameters of the first test elements by the row decoder and the column decoder of the test structure, wherein a number of the first pads is less than a number of the obtained first electrical parameters;
determining whether each of the first test elements is a weak element according to the first electrical parameters; and
selecting the weak element by the row decoder and the column decoder, and performing an abnormal-cause analysis on the weak element.

2. The test method of the semiconductor device according to claim 1, wherein selecting the first test elements, and obtaining the first electrical parameters of the first test elements by the row decoder and the column decoder of the test structure comprises:
receiving a row select signal and a column select signal through the first pads of the test structure, and providing the row select signal and the column select signal to the row decoder and the column decoder respectively, so as to control the row decoder and the column decoder to select one of the first test elements for testing; and
obtaining the first electrical parameter of each of the first test elements in a predetermined range by changing the row select signal and the column select signal.

3. The test method of the semiconductor device according to claim 1, wherein each of the first electrical parameters is a drain current.

4. The test method of the semiconductor device according to claim 1, wherein determining whether each of the first test elements is the weak element according to the first electrical parameters comprises:
comparing the first electrical parameters with a preset condition, such that the first test element having the first electrical parameter not meeting the preset condition is determined to be the weak element.

5. The test method of the semiconductor device according to claim 1, wherein selecting the weak element, and performing the abnormal-cause analysis on the weak element comprises:
selecting the weak element by the row decoder and the column decoder, and obtaining a second electrical parameter of the weak element; and
determining whether the second electrical parameter changes with a gate voltage to determine an abnormal type of the weak element.

6. The test method of the semiconductor device according to claim 5, wherein obtaining the second electrical parameter of the weak element comprises:
obtaining a gate current of the weak element from a corresponding one of the first pads coupled to the row decoder;
obtaining a drain current of the weak element from a corresponding one of the first pads coupled to the column decoder;
obtaining a source current of the weak element from a corresponding one of the first pads coupled to a source of the weak element; and
obtaining a well current of the weak element from a corresponding one of the first pads coupled to a well area of the weak element.

7. The test method of the semiconductor device according to claim 1, further comprising:
performing a coarse test on the test structure comprising a plurality of test partitions to obtain a coarse test electrical parameter of each of the test partitions; and
determining whether the test structure has an abnormal test partition according to the coarse test electrical parameter;
wherein selecting the first test elements, and obtaining the first electrical parameters of the first test elements by the row decoder and the column decoder of the test structure comprises:
performing a fine test on all the first test elements of the abnormal test partition to obtain the first electrical parameters of all the first test elements of the abnormal test partition.

8. The test method of the semiconductor device according to claim 7, wherein:
the test structure further comprises:
a second portion, including:
a second test element group comprising a plurality of second test elements; and
a second pad set comprising a plurality of second pads, each terminal of each of the second test elements being directly coupled to a corresponding one of the second pads,
the coarse test comprises applying a coarse test driving signal to the second pad set of the test structure so that the second test elements receive a coarse test driving voltage, and then obtaining the coarse test electrical parameters of the test partitions at the same time from the second test elements through the second pad set,
determining whether an abnormal test partition exists in the test structure according to the coarse test electrical parameter comprises comparing the coarse test electrical parameters of the respective test partitions with a preset condition, and determining a corresponding one of the test partitions as the abnormal test partition when its coarse test electrical parameter does not meet the preset condition,
wherein selecting the first test elements, and obtaining the first electrical parameters of the first test elements by the row decoder and the column decoder of the test structure comprises:
selecting the first test elements in the test structure corresponding to the abnormal test partition where the second test elements are located by the row decoder and the column decoder of the test structure.

9. A test structure of a semiconductor device, comprising:
a first portion, comprising:
a first test element group comprising a plurality of first test elements;
a first pad set comprising a plurality of first pads; and
a row decoder and a column decoder coupled between the first test element group and the first pad set, configured to select the first test elements, and obtain a plurality of first electrical parameters of the first test elements, wherein a number of the first pads is less than a number of the obtained first electrical parameters,
wherein it is determined whether each of the first test elements is a weak element according to the first electrical parameters, the weak element is selected by the row decoder and the column decoder, and an abnormal-cause analysis is performed on the weak element.

10. The test structure of the semiconductor device according to claim 9, wherein the row decoder and the column decoder respectively receive a row select signal and a column select signal through the first pad set, and obtain the first electrical parameter of each of the first test elements in a predetermined range by changing the row select signal and the column select signal.

11. The test structure of the semiconductor device according to claim 9, wherein the first electrical parameters are compared with a preset condition to determine the first test element having the first electrical parameter not meeting the preset condition to be the weak element.

12. The test structure of the semiconductor device according to claim 9, wherein the weak element is selected by the row decoder and the column decoder, a second electrical parameter of the weak element is obtained, and it is determined whether the second electrical parameter changes with a gate voltage to determine an abnormal type of the weak element.

13. The test structure of the semiconductor device according to claim 12, wherein the second electrical parameter comprises:
a gate current of the weak element obtained from one of the first pads coupled to the row decoder;
a drain current of the weak element obtained from one of the first pads coupled to the column decoder;
a source current of the weak element obtained from one of the first pads coupled to a source of the weak element; and
a well current of the weak element obtained from one of the first pads coupled to a well area of the weak element.

14. The test structure of the semiconductor device according to claim 9, further comprising:
a second portion, comprising:
a second test element group comprising a plurality of second test elements; an
a second pad set comprising a plurality of second pads, wherein each of ends of each of the second test elements is directly coupled to one of the second pads.

15. The test structure of the semiconductor device according to claim 14, wherein the first test element group has a plurality of first test partitions, the second test element group is configured the same as the first test element group and has a plurality of second test partitions, and each of the ends of one of the second test elements of each of the second test partitions is directly coupled to one of the second pads.

16. The test structure of the semiconductor device according to claim 15, wherein a coarse test is performed on each of the second test elements to obtain a coarse test electrical parameter of each of the second test partitions, it is determined whether the test structure has an abnormal test partition according to the coarse test electrical parameter, and a fine test is performed on all the first test elements corresponding to the abnormal test partition to obtain the first electrical parameters of all the first test elements of the abnormal test partition.

17. The test structure of the semiconductor device according to claim 16, wherein a number of the second pads is greater than a number of the obtained coarse test electrical parameters.
